(19) United States
(12) Patent Application Publication
(10) Pub. No.: US 2007/0292992 A1
(43) Pub. Date: Dec. 20, 2007

(54) METHOD OF ALIGNING A CONTACTLESS SEMICONDUCTOR DEVICE INTERFACE

(76) Inventor: Scott C. Best, Palo Alto, CA (US)

Correspondence Address: Shemwell Gregory & Courtney LLP, 4880 Stevens Creek Blvd., Ste 201, San Jose, CA, 95129-1034, US

(21) Appl. No.: 11/847,736

(22) Filed: Aug. 30, 2007

Related U.S. Application Data
(62) Division of application No. 11/106,229, filed on Apr. 13, 2005.

(51) Int. Cl. H01L 21/00; H01L 23/48

(52) U.S. Cl. 438/121; 257/774; 257/E21.001; 257/E23.01

(57) ABSTRACT

Contactless interconnects between an integrated circuit die and an electrical structure are aligned by charging alignment pads on the integrated circuit die to a first voltage, and charging counterpart alignment pads on the electrical structure to a second voltage. The integrated circuit die is disposed in an initial position relative to the electrical structure to develop an electrostatic aligning force between the charged alignment pads and their counterparts. When the integrated circuit die and electrical structure are enabled to move relative to one another, the electrostatic aligning force shifts the relative positioning of the integrated circuit die and electrical structure toward a desired alignment.

### CROSS-REFERENCE TO RELATED APPLICATIONS

This application is a division of, and hereby incorporates by reference, U.S. application Ser. No. 11/106,229 filed Apr. 13, 2005 and entitled “Semiconductor Device with Self-Aligning Contactless Interface.”

### FIELD OF THE INVENTION

The present invention relates to the field of high-speed signaling.

### BACKGROUND

Contactless interconnects, also called proximity interconnects, are finding increased application in modern chip-to-chip and chip-to-substrate interfaces. Because electrical contact to sensitive transistor structures during manufacture is unnecessary, electrostatic discharge (ESD) protection structures may be omitted, substantially reducing input/output (I/O) circuit footprint and therefore enabling higher interconnect density relative to traditional direct-contact interconnects. Unfortunately, contactless interconnects are susceptible to misalignment due to the smaller, more densely packed signal pads and loss of the aligning effect of solder (solder has an adhesive and tensile strength that helps overcome misalignment conditions in direct-contact systems). Although a number of circuit-based approaches have been developed to compensate for misalignment and to discriminate between acceptably aligned and misaligned interconnects, the added circuitry tends to consume significant additional power and die area.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates a method of aligning contactless interconnects on a pair of integrated circuit dice to form a multi-chip integrated circuit package having a contactless signaling interface;

FIG. 2 illustrates an exemplary embodiment of top and bottom dice having mirror-image distributions of alignment pads and signal pads;

FIG. 3 illustrates variations in misalignment force that may result with different patterns of alignment pads;

FIG. 4 illustrates application of a discharging probe to discharge alignment pads of an integrated circuit die after electrostatically-forced alignment is completed;

FIG. 5 illustrates an embodiment of an integrated circuit die having signal pads 105a disposed within an inner layer dielectric;

FIG. 6 illustrates an embodiment of an integrated circuit die having alignment pads that are electrically isolated from one another;

FIG. 7 illustrates a passive substrate having both alignment pads and signal pads on upper and lower faces to enable formation of electrostatically-aligned contactless interfaces with two integrated circuit die;

FIG. 8 illustrates an embodiment of an integrated circuit package that includes a base integrated circuit die and a number of additional integrated circuit dice coupled to the base die through electrostatically-aligned contactless interconnects;

FIGS. 9A and 9B illustrate embodiments for delivering power to an integrated circuit die having an electrostatically-aligned contactless interface;

FIGS. 10A and 10B illustrate embodiments of signal driver/receiver pairs that may be used for signal transmission and reception over electrostatically-aligned contactless interconnects;

FIG. 11A illustrates an integrated circuit die having primary and secondary alignment pads that are charged to different voltages;

FIG. 11B illustrates a pinching effect that may be ameliorated by disposing secondary alignment pads at or near a perimeter of the integrated circuit die of FIG. 11A;

FIG. 12 illustrates a distribution of primary alignment pads and secondary alignment pads of an integrated circuit die in a manner intended to reduce the total electrostatic alignment force; and

FIG. 13 illustrates a distribution of primary alignment pads and secondary alignment pads of an integrated circuit die in a manner intended to reduce the likelihood of a forced misalignment.

### DETAILED DESCRIPTION

In the following description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. Also signals referred to herein as clock signals may alternatively be strobe signals or other signals that provide event timing. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘ <̅s̅i̅g̅n̅a̅l̅ n̅a̅m̅e̅>̅’) is also used to indicate an active low signal. The term “coupled” is used herein to express a direct connection as well as connections through one or more intermediary circuits or structures. The term “exemplary” is used herein to express an example, not a preference or requirement.

Methods, devices and systems that employ electrostatic force to precisely align contactless interconnects are disclosed herein in various embodiments. In a number of embodiments, a set of electrically-isolated charge-receptive structures, referred to herein as alignment pads, are disposed in mirror-image patterns on signal I/O surfaces of electrical structures or components to be aligned. The alignment pads on the two components are charged to different voltages so that, when the components are brought into an initial face-to-face alignment, an appreciable electrostatic aligning force is developed between counterpart alignment pads. Consequently, when one of the components is freed to translate and/or rotate relative to the other, the aligning force pulls the freed component toward a desired alignment with the other component.

In one embodiment, the alignment pads on the components to be aligned are charged homogeneously to opposite voltages (+V, −V) selected to produce a desired level of aligning force. In an alternative embodiment, a subset of the alignment pads on one or both components may be charged to a different (e.g., opposite) voltage level than other alignment pads on the component, for example, to deter pinching or other misalignment, or to reduce the net aligning force. Also, the alignment pads on one or both components may be discharged after alignment is completed to prevent continued application of the aligning force. Further, the alignment pads may be disposed in random or predetermined patterns (and their counterparts in a mirror-image pattern) selected to reduce the probability of an electrostatically-forced misalignment. These and other embodiments are described below.

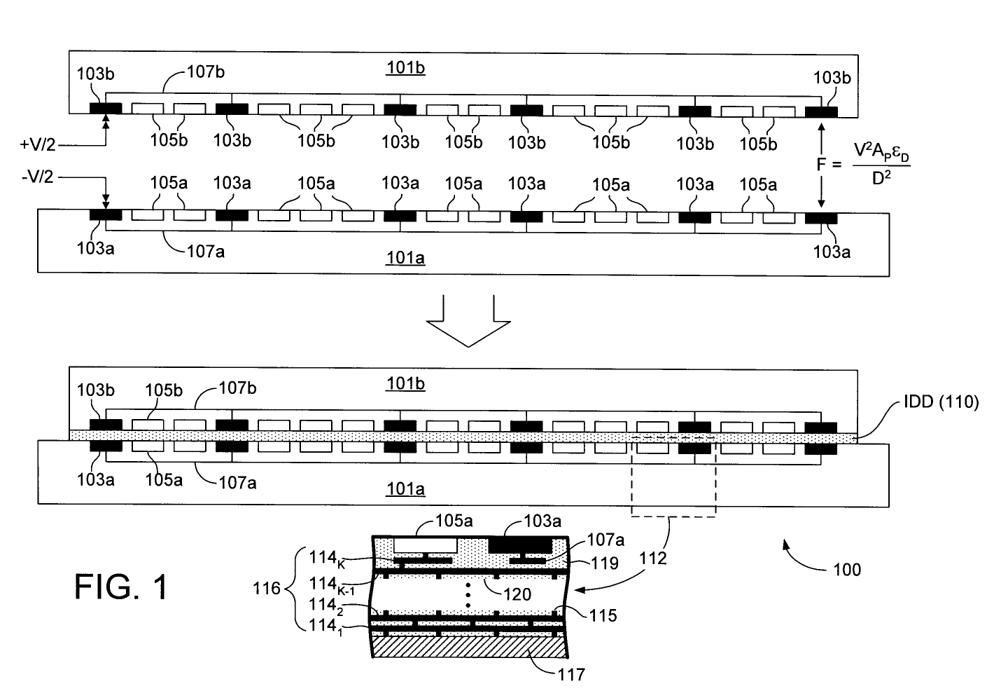

FIG. 1 illustrates a method of aligning contactless interconnects on a pair of integrated circuit dice 101a, 101b to form a multi-chip integrated circuit package 100 having a contactless signaling interface. Each integrated circuit die 101a, 101b includes both alignment pads 103a, 103b and signal pads 105a, 105b (contactless signal interconnection structures) and disposed, for example, in an array on its signal I/O surface. As shown in detail view 112 of integrated circuit die 101a, signal pads 105a are coupled through a conductive structure 116 (e.g., multiple conductive layers 114₁-114_{K} interconnected by vias 115 through insulating layers 120 as in a multi-layer metal process) to a semiconductor layer 117 (e.g., semiconductor substrate having doped regions therein, for example, to form source and drain terminals of MOS devices), while the alignment pads 103a are electrically isolated from the conductive structure and semiconductor layer by one or more oxide layers 119 or other insulating material. In the embodiment of FIG. 1, the alignment pads 103a of integrated circuit die 101a are coupled to one another, for example, by a conductive structure 107a formed in a metal layer, but are still electrically isolated by layer 119 from the larger conductive structure 116 and therefore from the semiconductor layer 117. The alignment pads 103b of integrated circuit die 101b are similarly coupled to one another by a conductive structure 107b, but electrically isolated from the semiconductor layer of the die. In alternative embodiments, structures 107a, 107b may be omitted in part or whole so that, within a given die, the alignment pads or subsets thereof are also electrically isolated from each. Also, in yet other embodiments, alignment pads 103a, 103b may be coupled to their respective semiconductor layers, so long as the pads are capable of storing a desired charge for a period of time sufficient to enable electrostatically forced alignment between the integrated circuit dice.

Still referring to FIG. 1, the alignment pads 103a, 103b of the two dice 101a, 101b are charged to opposite voltages (+V/2 and −V/2 in the example shown) so that, when the dice are brought into an initial face-to-face alignment, an electrostatic force of attraction is developed between the charged alignment pads on one die and their oppositely charged counterparts on the other die, electrostatically forcing the two dice toward a desired alignment with one another. Consequently, when one of the integrated circuit dice is released, for example from a robotic handler, the released die is enabled to translate along any or all of three orthogonal axes, and/or rotate about any or all of the three axes, in response to the electrostatic alignment force and thus achieve a precisely desired alignment relative to the other integrated circuit die. After the dice have been electrostatically aligned, accurate alignment may be confirmed, for example, through physical measurement and/or various electrical testing techniques (e.g., signaling tests to confirm operation of the contactless interconnects at all or selected locations in the interconnect array).

As shown in FIG. 1, an inter-device dielectric 110 (IDD) is disposed between the signal I/O surfaces of the integrated circuit dice 101a, 101b to form a medium through which signals may be capacitively or inductively coupled. Though not specifically shown, conductive structures may be disposed in the IDD 110 to enable direct-contact signaling and/or power or other connections between the integrated circuit dice 101a, 101b in addition to the contactless interconnects established by counterpart signal pads 105a, 105b. The IDD 110 may additionally perform an adhesive function, bonding the integrated circuit dice 101a, 101b together. In one embodiment, the IDD 110 is formed integrally with one or both of the integrated circuit dice 101a, 101b, for example, by a final oxide layer. In such an embodiment, a conductive via or other structure may be provided to establish a charging node for charging the alignment pads 103a, 103b. In an alternative embodiment, the IDD 110 is formed separately from the integrated circuit dice 101a, 101b, for example as a web or sheet of dielectric material or as a viscous material, and applied to the face of one or both integrated circuit dice 101a, 101b before they are brought into an initial face-to-face alignment. In the case of a viscous dielectric material, temporary or permanent spacing structures may be disposed on the signal I/O surface of one or both integrated circuit dice 101a, 101b to maintain a uniform IDD thickness as the electrostatic alignment force pulls the dice toward one another (i.e., spacers to prevent the dice 101a, 101b from pinching the IDD 110).

Still referring to FIG. 1, the electrostatic force between any counterpart pair of alignment pads 103a, 103b may be expressed as F=(V²A_{P}∈_{D})/D², and is thus proportional to the face area of the pads (A_{P}), the permittivity (∈_{D}) of the IDD 110 (which may also be expressed as K_{D}∈₀, the product of the dielectric constant of the IDD 110 (K_{D}) and the permittivity of free space), the square of the charge differential (V) between the pads, and the inverse square of the distance (D) between the pads. Accordingly, the total electrostatic alignment force may be readily increased or decreased by adjusting the charging voltages to any value that does not damage the insulating layer adjacent the alignment pads (e.g., silicon dioxide insulating layers generally do not rupture at voltages below 50 volts). Also, to achieve a desired range of voltage-controlled electrostatic force, the thickness of the IDD may be increased or decreased (thus adjusting the distance between counterpart pads), the number of alignment pads may be increased or reduced (thus increasing or reducing the net alignment pad face area), and/or materials having higher or lower dielectric constants may be used to implement the IDD.

Automated test equipment (ATE) or other equipment capable of probing the alignment pads 103a, 103b may be used to charge the alignment pads to the desired voltage level. In embodiments in which the alignment pad network is isolated from other electrical structures, the charge placed on the alignment pads may remain indefinitely, allowing a first piece of ATE equipment to place the charge, and a second machine to subsequently package the device later in the manufacturing process. Also, in one embodiment, a conductive structure referred to herein as a charging node may be coupled to the alignment pads of a given die and used as a landing for a charging probe of the ATE or other charge source. In alternative embodiments, the alignment pads themselves or a subset of the alignment pads may be used as charging nodes.

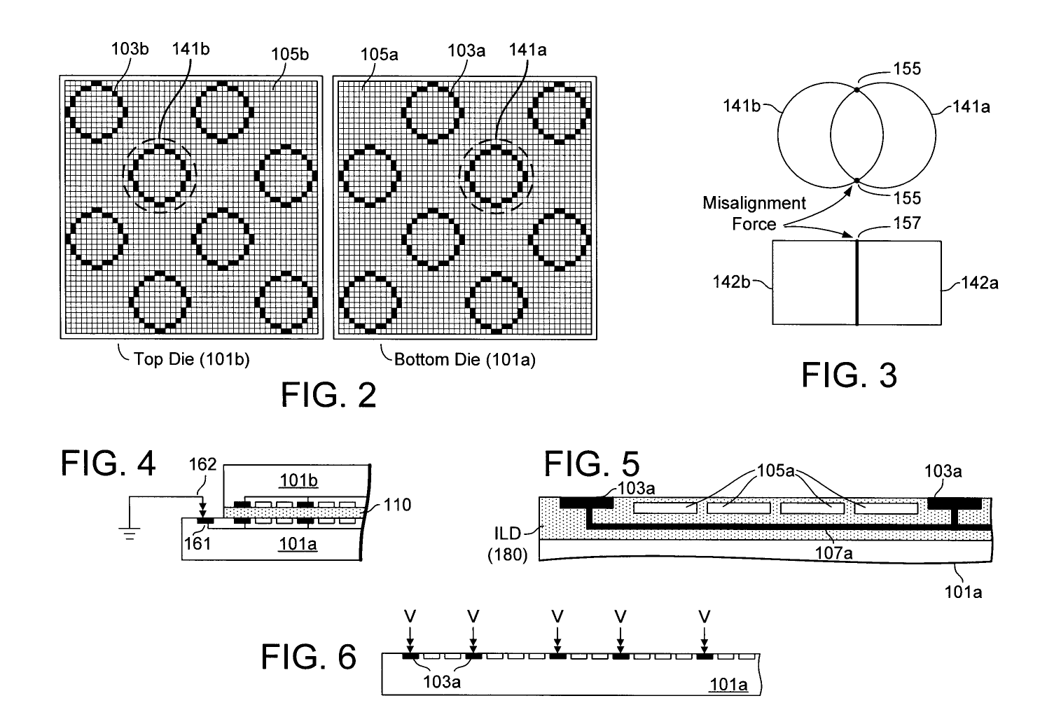

FIG. 2 illustrates an exemplary embodiment of top and bottom dice 101a, 101b having mirror-image distributions of alignment pads 103a, 103b and signal pads 105a, 105b. By this arrangement, when the alignment pads 103a, 103b (shown in black) are charged and the top die 101a is flipped to face the bottom die 101b, the alignment pads 103a are disposed opposite their counterparts 103b to develop the electrostatic alignment force discussed above. In the embodiment shown, the alignment pads 103a, 103b are disposed in circular patterns 141a, 141b to reduce the likelihood of an electrostatically-forced misalignment. That is, as shown in FIG. 3, in a misalignment of counterpart circular patterns 141a, 141b, only the relatively small number of alignment pads at junctions 155 will be disposed opposite one another, thereby generating a relatively weak attractive force (i.e., weak misalignment force) that may be readily overcome by the greater electrostatic force of the desired alignment. Also, the misalignment condition does not yield a relative maximum alignment force (i.e., does not create a metastable misalignment). By contrast, alignment pads disposed in rectangular patterns 142a, 142b are susceptible to a significantly stronger misalignment force that occurs when opposite edges of the patterns come into proximity with one another, as shown at 157 (also creating a metastable misalignment as overcoming the misalignment involves moving from a relatively strongly forced misalignment to a weaker-force alignment before the desired alignment is reached). Accordingly, while virtually any pattern of alignment pads may be used (including a random or pseudo random pattern), in one embodiment, alignment pads are disposed in patterns specifically selected to increase the ratio of alignment force to misalignment force and/or to avoid metastable misalignment, thus reducing the likelihood of electrostatically-forced misalignment.

In embodiments having a compliant IDD (e.g., a viscous IDD 110 as discussed in reference to FIG. 1), continued application of the electrostatic alignment force after alignment has been achieved may result in undesired pinching or other progressive compression of the IDD. In such embodiments, it may be desirable to discharge the alignment pads of one or both integrated circuit die after the dice have been secured in the desired alignment (which securing may be accomplished, for example, by flash-curing a light-sensitive epoxy and/or through application of other adhesive materials or fastening structures). Referring to FIG. 4, for example, after integrated circuit dice 101a and 101b have been secured in a desired alignment, a probe 162 is applied to a charge/discharge node 161 of integrated circuit die 101a to discharge the die's alignment pads (e.g., discharge to ground). Noting that integrated circuit die 101a is shown as extending beyond the edge of die 101b, die 101b may likewise extend beyond one or more edges of die 101a to expose a charging node that may be used to charge/discharge the alignment pads of die 101b.

In one embodiment, illustrated in FIG. 5, at least one of the alignment pads 103a of integrated circuit die 101a is exposed to act as a charging node, while signal pads 105a are disposed within an inner layer dielectric 180 (ILD). By this arrangement, the signal pads 105a are protected from ESD during pre-assembly handling. As shown in FIG. 6, the alignment pads 103a or any subset thereof may be isolated not only from the semiconductor layer and conductive structure coupled thereto, but also from each other (i.e., conductive structure 107a described in reference to FIG. 1 may be omitted). In such an embodiment, each of the alignment pads 103a (or groups of alignment pads) may be charged simultaneously by a respective charging probe, or a single charging probe (or some number of probes less than the number of alignment pads or groups of alignment pads to be charged) may be stepped from alignment pad to alignment pad to charge each in turn.

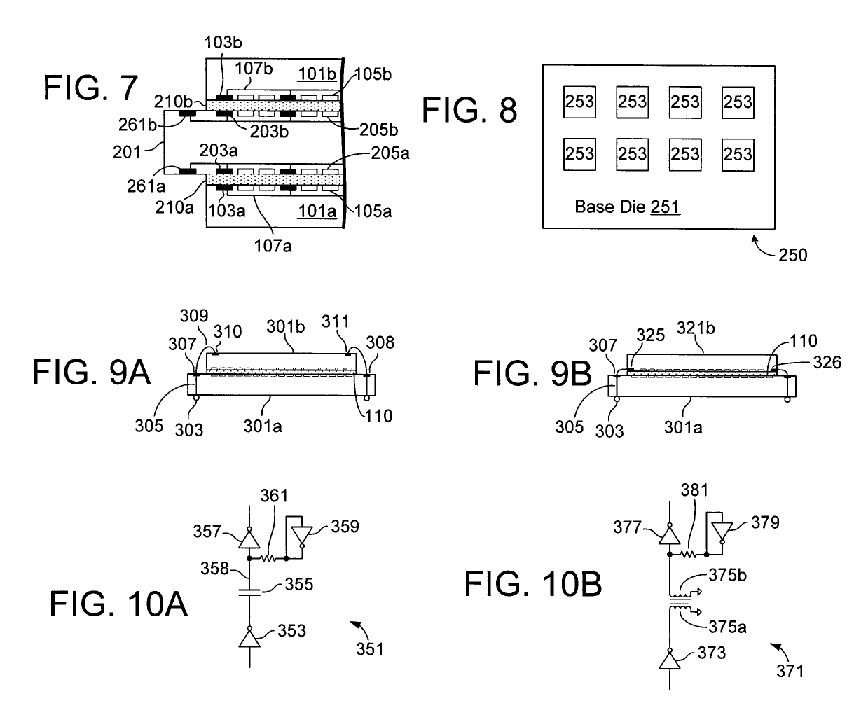

Although alignment of contactless interconnects between integrated circuit devices have been discussed thus far, the principles and techniques disclosed are not limited to integrated circuit devices (i.e., semiconductor substrates having transistors formed thereon and interconnected by one or more conductive layers), but rather may be applied more generally to establish an electrostatically aligned contactless interface between any pair of electrical structures, including, for example and without limitation, between an integrated circuit die and a passive substrate, or between two or more passive substrates. The passive substrate may be, for example, a signal distribution substrate within an integrated circuit package, or a printed circuit board, such as a daughter card or motherboard. FIG. 7, for example, illustrates a passive substrate 201 having alignment pads 203a, 203b and signal pads 205a, 205b on opposite faces thereof to enable formation of electrostatically-aligned contactless interfaces with two integrated circuit dice 101a, 101b. The passive substrate 201 may have any number of conductive paths (not shown) for interconnecting the signal pads 205a, 205b with the signal pads 105a, 105b of the integrated circuit dice 101a, 101b and/or with other devices. The passive substrate 201 may also include power and ground delivery structures (e.g., power buses) to deliver power to either or both of the integrated circuit dice 101a, 101b, for example, through conductive vias in IDDs 210a and 210b, wire bonds or other conductive structures. In the embodiment shown, dedicated charging nodes 261a and 261b are provided for charging and discharging the alignment pads 203a and 203b, respectively, on the passive substrate 201. As in embodiments discussed above, the charging nodes 261 may be omitted in alternative embodiments, and one or more of the alignment pads 203 used as charging nodes and/or with each of the alignment pads 203 constituting its own charging node and being individually charged. Also, while the substrate 201 is depicted as having contactless interconnects to two integrated circuit dice 101a and 101b, the integrated circuit dice may be other types of substrates (e.g., other passive substrates) in alternative embodiments and, additional substrates (including additional integrated circuit dice) may be coupled on one or both sides the passive substrate 201 as area permits.

FIG. 8 illustrates an embodiment of an integrated circuit package or system 250 that includes a base integrated circuit die 251 (or group of die), and a number of additional integrated circuit dice 253 coupled to the base die through electrostatically-aligned contactless interconnects. In the particular embodiment shown, for example, the base die 251 includes an intercoupled processor and memory controller, and each of the dice 253 is a memory device, thus effecting a data processing system within a single integrated circuit package. In one embodiment, the memory devices 253 form a homogeneous memory array of dynamic random access memory (DRAM), static random access memory (SRAM), read-only memory (ROM, including electrically erasable programmable ROM (EEPROM) such as flash EEPROM) or any other desirable memory type. In alternative embodiments, the memory devices 253 may be different from one another to form hybrid memory arrays of different types of memory. For example, in one embodiment, one or more of the memory devices 253 are DRAM devices to form a primary operating memory, one or more of the memory devices 253 are SRAM devices to form low latency memories (e.g., cache memories), and one or more of the memory devices 253 are flash EEPROM devices that form non-volatile storage for boot-up program code and other information to be retained after system power down. Also, instead of a memory device, one or more of dice 253 may be an integrated circuit device specialized for performing other functions needed by the data processing system (e.g., a network interface, a peripheral bus bridge, etc).

FIG. 9A illustrates an embodiment for delivering power to an integrated circuit die 301b having an electrostatically-aligned contactless interface with electrical structure 301a. As in embodiments discussed above, the electrical structure 301a may be a passive substrate or another integrated circuit die. In the embodiment shown, conductive contacts 303 on the underside of the electrical structure 301a are coupled through a conductive structure 305 (e.g., vias or a combination of vias and metal layers) to a power node 307 on the signal I/O surface of the electrical structure 301a. A similar structure is formed at the opposite end of the electrical structure for a ground node 308. The power and ground nodes 307, 308 may be wire bonded (e.g., as shown at 309) or otherwise coupled to counterpart power and ground nodes 310, 311 on die 301b. By this arrangement, when the electrical structure 301a is coupled to a power source, supply and ground voltages are supplied to the electrical structure 301a and to the integrated circuit die 301b. In an alternative embodiment, illustrated in FIG. 9B, rather than powering an integrated circuit die 321b through power and ground connections on the backside of the die 321b (i.e., the side opposite the signal I/O side of die 321b), power and ground nodes 325, 326 are formed at the edge of the signal I/O surface of the die. More generally, power may be delivered to an electrostatically-aligned integrated circuit die in virtually any manner with out departing from the scope of the present invention. For example, rather than providing power through direct connection to a power supply, power may be delivered through magnetic coupling of counterpart inductive structures (e.g., disposed on the signal I/O surfaces of aligned components) that act as primary and secondary transformer coils.

FIGS. 10A and 10B illustrate embodiments of signal driver/receiver pairs that may be used for signal transmission and reception over the contactless interconnects described above. In the driver/receiver pair 351 of FIG. 10A, the signal I/O pads of a contactless interconnect and the inter-device dielectric form a capacitive interconnect 355 (i.e., a capacitive coupling) between the output of a signal driver 353 and the input of a signal receiver 357. Though depicted as an inverter in FIG. 10A, the signal driver 353 may be implemented by virtually any signal-generating circuit. Signal coding may be used to ensure that the transmitted signal has sufficient transition density and therefore sufficient frequency content to traverse the capacitively coupled interconnect without undue attenuation.

In the embodiment of FIG. 10A, the signal receiver 357 includes a signal-reception inverter 357 having an input coupled to a signal I/O pad (modeled by one plate of the capacitive interconnect 355) and, via resistive element 361, to a DC-bias generator 359. The DC-bias generator (formed, for example, by an input-to-output-coupled inverter as shown) is used to establish a DC-bias level at node 358 (i.e., at the input of inverter 357) that is nominally mid-way between high and low signal levels, and thus enables the capacitively-coupled incoming signal to drive the voltage level at node 358 above and below the DC-bias point, causing inverter 357 to generate a corresponding binary output.

In the driver/receiver pair 371 of FIG. 10B, the signal driver and signal receiver are inductively coupled (i.e., instead of capacitively coupled), but otherwise operate in generally the same manner as the driver/receiver pair 351 of FIG. 10A. That is, driver circuit 373 includes an inverter or other circuit capable of driving an inductive load 375a (which may be the signal pad itself, or may include a coiled structure, for example, formed around or in place of the signal pad), and the receiver circuit includes signal-reception inverter 377 having an input coupled to an inductive structure 375b (which also may be the signal pad itself or may include a pickup coil formed around or in place of the signal pad) and, via resistor 381, to a DC-bias generator 379. Although not specifically shown in FIGS. 10A and 10B, the signal driver/receiver pairs may additionally include, without limitation, timing circuitry to allow synchronous signal transmission and reception, clock-data recovery (CDR) circuitry, equalization circuitry (e.g., transmit pre-emphasis circuitry, decision-feedback equalization circuitry and circuitry for statically or dynamically controlling selection of tap latencies and/or tap weights for same), and/or circuitry to enable multi-level signaling (i.e., more than one bit per transmitted symbol) over all or a subset of the contactless interconnects. Further, calibration circuitry may also be provided to enable one-time, periodic or event-driven calibration of DC-bias setpoints or other operating characteristics of the driver/receiver pairs.

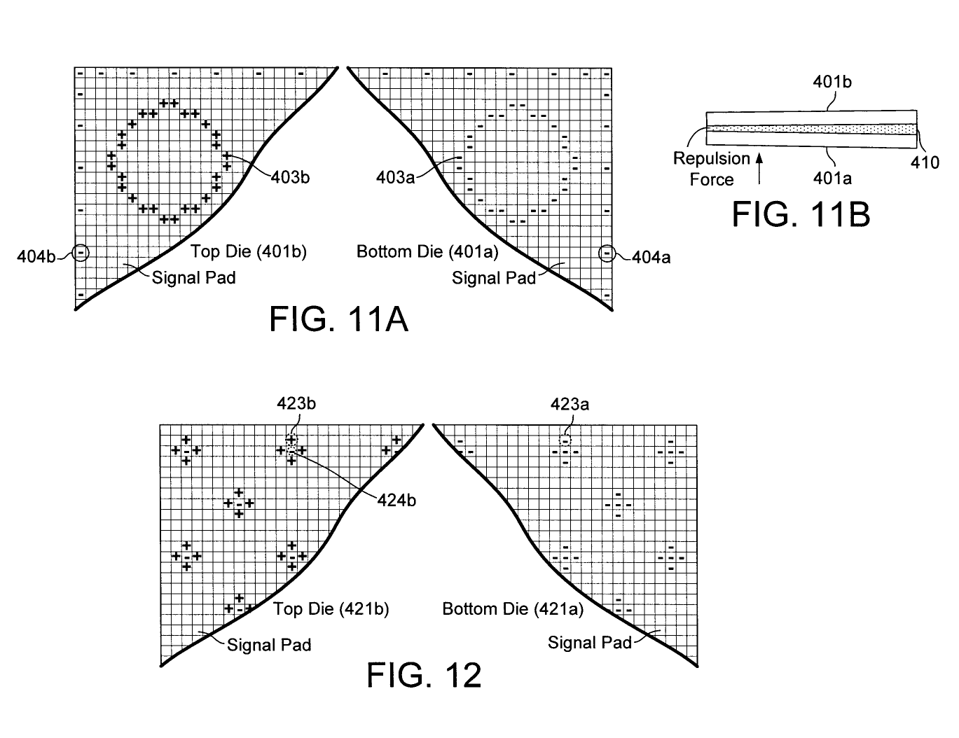

In the embodiments of FIGS. 1 and 2, electrostatically-forced alignment of contactless interconnects is achieved through homogeneous charging of the alignment pads on the components to be aligned. In alternative embodiments, the alignment pads of one or both of the components may be charged to different voltages than other alignment pads on that same component. Referring to FIG. 11A, for example, a primary set of alignment pads 403b (marked by ‘+’ symbols) on a top die 401b may be charged to a positive voltage, while a secondary set of alignment pads 404b (marked by ‘−’ symbols) are charged to a negative voltage. By this arrangement, when the top die 401b is brought into an initial face-to-face alignment with a bottom die 401a (or other electrical structure) having counterpart alignment pads 403a that have all been charged to the negative voltage, the primary alignment pads 403b of the top die 401b will be attracted to their counterparts 403a on the bottom die 401a (thus generating an attractive electrostatic alignment force), while the secondary alignment pads 404b of the top die will be repelled by their counterparts 404a on the bottom die 401a. As shown in FIG. 11B, by placing the secondary alignment pads 404b at or near the periphery of the die (or at or near the periphery of the interconnect array), the repulsion force counteracts pinching of the inter-device dielectric 410 (e.g., at the edges of the die) that might otherwise occur if one side of the die 401b is initially placed (or moves) closer to the counterpart die 401a than the other. Although the primary alignment pads 403b are disposed in circular patterns in the embodiment of FIG. 11A, other patterns or a random pad distribution may be used in alternative embodiments. Also, while the secondary alignment pads 404b are depicted in a particular density and distribution pattern, other densities and distribution patterns may be used in alternative embodiments (e.g., more or fewer perimeter pads and/or interior pads may be allocated to secondary alignment pads). Also, separate charging nodes may be provided for the primary and secondary alignment pads (or subsets thereof) or, as discussed above, each alignment pad may constitute its own charging node.

FIG. 12 illustrates a distribution of primary alignment pads 423b and secondary alignment pads 424b on a top die 421b in a manner intended to reduce the total electrostatic alignment force. In the particular embodiment shown, secondary alignment pads 424b are disposed within diamond-shaped patterns of primary alignment pads 423b and charged to a voltage that will repel counterpart alignment pads 423a of a bottom die 421a, thus providing a measure of repulsion force to counteract the attractive alignment force. The number of secondary alignment pads may be selected to limit the net electrostatic alignment force to a desired level. Also, as in the embodiment of FIG. 11A, other patterns and densities of primary and secondary alignment pads may be used in alternative embodiments, and separate charging nodes may be provided for the primary and secondary alignment pads (or subsets thereof) or each alignment pad may constitute its own charging node.

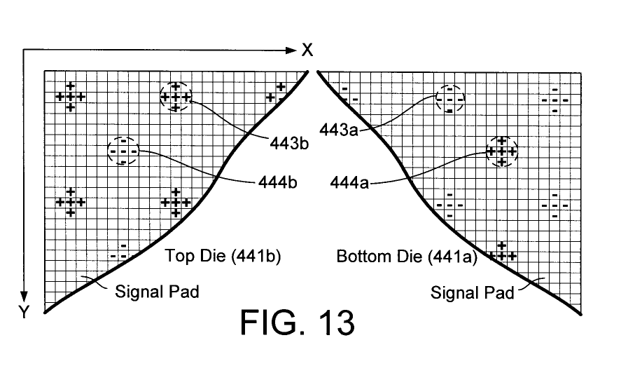

FIG. 13 illustrates a distribution of primary alignment pads 443b and secondary alignment pads 444b on a top die 441b and a bottom die 441a in a manner intended to reduce the likelihood of a forced misalignment. In the particular embodiment shown, primary alignment pads 443b are arranged in cross-shaped patterns that are distributed at even intervals along X and Y axes of the top die, and the secondary alignment pads 444b are likewise arranged in cross-shaped patterns that are distributed in even intervals along the X and Y axes, but offset from the primary alignment pad distribution by a half interval in both the X and Y directions. The primary alignment pads 443a and secondary alignment pads 444a of the bottom die 441a are arranged to mirror the distribution of primary and secondary alignment pads of the top die 441b, but are oppositely charged so that, when the top and bottom dice are brought into a proper initial alignment, the primary alignment pads 443a, 443b will attract one another and the secondary alignment pad 444a, 444b will also attract one another. If the two dice are brought into an initial alignment in which primary pads of one die are opposite secondary pads of the other, an electrostatic repulsion force will develop, driving the two dice away from the misaligned condition and toward a more aligned condition. As in the embodiments of FIGS. 11A and 12, other patterns and densities of primary and secondary alignment pads may be used in alternative embodiments, and separate charging nodes may be provided for the primary and secondary alignment pads (or subsets thereof) or each alignment pad may constitute its own charging node.

It should be noted that the various circuits disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.).

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

Various aspects and features of embodiments disclosed herein are set forth, for example and without limitation, in the following numbered clauses:

1. An integrated circuit device comprising:

a semiconductor layer;
a conductive structure coupled to the semiconductor layer;
a first insulating layer disposed on the conductive structure; and
a plurality of electrostatic alignment pads disposed on, and electrically isolated from the semiconductor layer by, the first insulating layer.
   2. The integrated circuit device of clause 8 further comprising:
a plurality of signal pads disposed on the first insulating layer adjacent the electrostatic alignment pads; and
conductive vias that extend through the first insulating layer, from the plurality of signal pads to the conductive structure, to couple the plurality of signal pads to the semiconductor layer.
   3. The integrated circuit device of clause 9 further comprising a second insulating layer disposed over the first insulating layer and covering at least a subset of the signal pads.
   4. The integrated circuit device of clause 8 further comprising a first charging node coupled to at least a first subset of the electrostatic alignment pads.
   5. The integrated circuit device of clause 11 wherein the first charging node is exposed to enable contact with a first external charging source.
   6. The integrated circuit device of clause 11 further comprising a second charging node coupled to a second subset of the electrostatic alignment pads and exposed to enable contact with a second external charging source.
   7. The integrated circuit device of clause 8 wherein the semiconductor layer includes a plurality of transistors and the conductive structure comprises a plurality of metal layers coupled to one another and to the plurality of transistors by conductive vias.
   8. The integrated circuit device of clause 8 wherein the semiconductor layer comprises a semiconductor substrate having doped regions disposed therein to form transistor terminals.
   9. The integrated circuit device of clause 15 wherein the conductive structure is coupled to the doped regions.
   10. The integrated circuit device of clause 8 wherein the plurality of electrostatic alignment pads are disposed in a predetermined pattern.
   11. The integrated circuit device of clause 17 wherein the predetermined pattern comprises at least one substantially circular arrangement of at least a subset of the plurality of electrostatic alignment pads.
   12. An integrated circuit package comprising:
a first integrated circuit die having a semiconductor layer and a first plurality of alignment pads that are electrically isolated from the semiconductor layer; and
an electrical structure disposed adjacent the first integrated circuit die and having a second plurality of alignment pads each aligned face-to-face with a counterpart one of the first plurality of alignment pads.
   13. The integrated circuit package of clause 19 wherein the electrical structure comprises a second integrated circuit die having a semiconductor layer that is electrically isolated from the second plurality of alignment pads.
   14. The integrated circuit package of clause 20 wherein the first integrated circuit die comprises a memory device and the second integrated circuit die comprises a memory controller.
   15. The integrated circuit package of clause 21 wherein the second integrated circuit die further comprises a processor coupled to the memory controller.
   16. The integrated circuit package of clause 20 wherein the first integrated circuit die comprises a first plurality of signal pads coupled to the semiconductor layer and the electrical structure comprises a second plurality of signal pads that are aligned face-to-face with the first plurality of signal pads to form a contactless signaling interface.
   17. The integrated circuit package of clause 23 wherein the electrical structure comprises a second integrated circuit die having a semiconductor layer that is electrically isolated from the second plurality of alignment pads.
   18. The integrated circuit package of clause 24 wherein the first integrated circuit die comprises a memory device, the second integrated circuit die comprises a memory controller, and the contactless signaling interface comprises a data transfer path between the memory controller and the memory device.
   19. The integrated circuit package of clause 23 further comprising at least one dielectric layer disposed between the first plurality of signal pads and the second plurality of signal pads.
   20. The integrated circuit package of clause 19 wherein the electrical structure comprises a passive substrate.
   21. The integrated circuit package of clause 19 further comprising a dielectric layer disposed between the first integrated circuit die and the electrical structure.
   22. The integrated circuit package of clause 19 wherein the first plurality of alignment pads and the second plurality of alignment pads are disposed in respective patterns that are mirror images of one another.
   23. The integrated circuit package of clause 29 wherein the respective patterns each include at least one substantially circular pattern.
   24. An integrated circuit device comprising a plurality of alignment pads to enable electrostatically-forced alignment with an electrical structure having a plurality of counterpart alignment pads, wherein the plurality of alignment pads is disposed in a predetermined pattern selected, at least in part, to reduce the possibility of electrostatically-forced misalignment between the integrated circuit device and the electrical structure.
   25. The integrated circuit device of clause 31 wherein the predetermined pattern comprises at least one substantially circular pattern.
   26. The integrated circuit device of clause 31 wherein the electrical structure is also an integrated circuit device.
   27. An integrated circuit device comprising:
a plurality of contactless interconnect structures; and
a plurality of alignment structures to enable electrostatically-forced alignment with an electrical structure having a counterpart plurality of alignment structures and a counterpart plurality of contactless interconnect structures.
   28. The integrated circuit device of clause 34 wherein the plurality of contactless interconnect structures comprise a plurality of contactless signal pads.
   29. The integrated circuit device of clause 34 wherein the integrated circuit device further comprises:
a semiconductor layer;
a conductive structure to couple the semiconductor layer to the plurality of contactless interconnect structures; and
insulating material to electrically isolate the plurality of alignment structures from the semiconductor layer.
   30. The integrated circuit device of clause 34 wherein at least a portion of the plurality of alignment structures are coupled to one another.
   31. The integrated circuit device of clause 34 wherein the electrical structure is also an integrated circuit device.
   32. Computer readable media having information embodied therein that includes a description of an apparatus, the information including descriptions of:
a plurality of contactless interconnect structures within an integrated circuit die; and
a plurality of alignment structures within the integrated circuit die to enable electrostatically-forced alignment between the integrated circuit die and an electrical structure having a counterpart plurality of alignment structures and a counterpart plurality of contactless interconnect structures
   33. An integrated circuit package comprising:
an electrical structure; and
an integrated circuit die having means for electrostatically forcing a desired alignment between the integrated circuit die and the electrical structure.

Although the invention has been described with reference to specific embodiments thereof, it will be evident that various modifications and changes may be made thereto without departing from the broader spirit and scope of the invention. Accordingly, the specification and drawings are to be regarded in an illustrative rather than a restrictive sense. In the event that provisions of any document incorporated by reference herein are determined to contradict or otherwise be inconsistent with like or related provisions herein, the provisions herein shall control at least for purposes of construing the appended claims.

What is claimed is:

1. A method of aligning an integrated circuit die to an electrical structure, the method comprising:
charging a plurality of alignment pads on the integrated circuit die to a first voltage;
charging a plurality of counterpart alignment pads on the electrical structure to a second voltage;
disposing the integrated circuit die in an initial position relative to the electrical structure to develop an electrostatic aligning force between the plurality of alignment pads and the plurality of counterpart alignment pads; and
enabling relative movement between the integrated circuit die and the electrical structure in response to the electrostatic aligning force.

2. The method of claim 1 wherein enabling relative movement between the integrated circuit die and the electrical structure comprises releasing either the integrated circuit die or the electrical structure from a secured position.

3. The method of claim 2 wherein releasing either the integrated circuit die or the electrical structure from a secured position comprises enabling either the integrated circuit die or the electrical structure to translate along at least one of three orthogonal axes.

4. The method of claim 3 wherein releasing either the integrated circuit die or the electrical structure from a secured position comprises enabling either the integrated circuit die or the electrical structure to rotate about at least one of three orthogonal axes.

5. The method of claim 1 wherein the electrical structure is an integrated circuit die.

6. The method of claim 1 further comprising disposing a layer of dielectric material between the integrated circuit die and the electrical structure.

7. The method of claim 1 wherein the integrated circuit die comprises a plurality of signal pads and the electrical structure comprises a plurality of counterpart signal pads, and wherein enabling relative movement between the integrated circuit die and the electrical structure comprises aligning the plurality of signal pads with the plurality of counterpart signal pads to form a contactless signaling interface.

8. The method of claim 1 further comprising disposing the plurality of alignment pads on the integrated circuit die in a predetermined pattern.

9. The method of claim 8 wherein the predetermined pattern is selected, at least in part, to reduce the possibility of electrostatically-forced misalignment between the integrated circuit die and the electrical structure.

10. The method of claim 9 wherein the predetermined pattern comprises at least one substantially circular arrangement.

11. An integrated circuit package comprising:
means for charging a plurality of alignment pads on an integrated circuit die to a first voltage;
means for charging a plurality of counterpart alignment pads on an electrical structure to a second voltage;
means for disposing the integrated circuit die in an initial position relative to the electrical structure to develop an electrostatic aligning force between the plurality of alignment pads and the plurality of counterpart alignment pads; and
means for enabling relative movement between the integrated circuit die and the electrical structure in response to the electrostatic aligning force.
